(19) United States
(12) Patent Application Publication
(10) Pub. No.: US 2015/0262728 A1
(43) Pub. Date: Sep. 17, 2015

(54) ELECTRICALLY CONDUCTIVE PASTE COMPOSITION AND METHOD OF FORMING AN ELECTRICAL CIRCUIT ON A POLYMER SUBSTRATE

(71) Applicant: E I DU PONT DE NEMOURS AND COMPANY, Wilmington, DE (US)

(72) Inventor: TOSHIAKI OGIWARA, Tochigi-Ken (JP)

(73) Assignee: E I DU PONT DE NEMOURS AND COMPANY, Wilmington, DE (US)

(21) Appl. No.: 14/203,891

(22) Filed: Mar. 11, 2014

(51) Int. Cl. H01B 1/22; H05K 3/12

(52) U.S. Cl. CPC H01B 1/22; H05K 3/1283

(57) ABSTRACT

An electrically conductive paste composition for forming an electrical circuit comprising: (a) a flake-shaped silver powder, wherein the mean particle size (D50) of the silver powder is 2.0 to 8.0 μm; and (b) a polyvinyl acetal resin, wherein the viscosity of a 10 wt % solution of the polyvinyl acetal resin in di-propylene glycol methyl ether is no less than 1 Pa·s as measured with a Brookfield viscometer (10 rpm, at 25° C.); and wherein the weight ratio of (a) to (b) is in the range from 87/13 to 95/5.

### FIELD OF THE INVENTION

This invention relates to conductive compositions, and, in particular, relates to conductive compositions applicable for forming a conductive circuit pattern on a printed board.

### TECHNICAL BACKGROUND OF THE INVENTION

Conductive compositions containing a conductive powder and a resin are used for forming a circuit pattern with low resistivity. Such compositions can be applied or printed on a substrate and then cured. In cases the substrate is composed of light-weight plastic such as polycarbonate, it is desired to keep the heating temperature and the curing temperature low in order to prevent the damage to the substrate. WO2013/161966 discloses a conductive composition that can be cured at low temperatures to form a conductive pattern with low resistivity.

### SUMMARY OF THE INVENTION

In one aspect, the present invention relates to an electrically conductive paste composition for forming an electrical circuit comprising: (a) a flake-shaped silver powder, wherein the mean particle size (D50) of the silver powder is 2.0 to 8.0 μm; (b) a polyvinyl acetal resin, wherein the viscosity of a 10 wt % solution of the polyvinyl acetal resin in di-propylene glycol methyl ether is no less than 1 Pa·s as measured with a Brookfield viscometer (10 rpm, at 25° C.); and wherein the weight ratio of (a) to (b) is in the range from 87/13 to 95/5.

In another aspect, the present invention relates to a method of forming an electrical circuit on a polymer substrate, comprising the steps of:
(1) applying an electrically conductive paste comprising (a) flake-shaped silver powders, wherein the mean particle size (D50)
(2) of the silver powders is 2.0 to 8.0 μm; and (b) polyvinyl acetal resin, wherein the viscosity of a 10 wt % solution of the polyvinyl acetal resin in di-propylene glycol methyl ether is no less than 1 Pa·s as measured with a Brookfield viscometer (10 rpm, at 25° C.); and wherein the weight ratio of (a) to (b) is in the range from 87/13 to 95/5 onto the polymer substrate, thereby forming an electrical conductor pattern; and
(3) heat-curing the formed electrical conductor pattern at 120° C. or lower.

### BRIEF DESCRIPTION OF THE DRAWINGS

FIG. 1 shows a schematic cross-sectional drawing of an antenna structure of vehicle, including a polymer substrate on which an electrically conductive circuit pattern has been formed.

FIG. 2 shows a schematic cross-sectional drawing of an antenna structure of vehicle, including laminated polymer substrates and between which an electrically conductive circuit pattern has been formed.

FIG. 3 is a schematic drawing of an antenna structure of vehicle, including a polymer substrate on which an electrically conductive circuit pattern has been formed.

FIG. 4 shows a schematic drawing of a circuit pattern formed using an electrically conductive paste composition on a substrate fabricated to measure electrical resistivity (μΩ·cm).

### DETAILED DESCRIPTION OF THE INVENTION

### Electrically Conductive Paste Composition

In one embodiment of the present invention, the electrically conductive paste composition comprises: (a) silver powders and (b) polyvinyl acetal resin, wherein a weight ratio of (a) to (b) is in the range from 87/13 to 95/5.

### (a) Silver Powders

The silver powders comprise flake-shaped silver powders, in one embodiment. In the present embodiment, electrical resistivity can be effectively reduced by using the flake-shaped silver powders. In the present description, unless otherwise noted, the term “electrical resistivity” means lateral electrical resistivity and it refers to a measured value obtained by placing probes on both ends of a formed line. The specific measurement methods thereof are specifically described in the examples of the present description.

Examples of the Above-Mentioned Flake-Shaped Silver Powders

In one embodiment, the flake-shaped silver powders include scaly shape, rod-shaped and plate-shaped silver powders. In one embodiment, the flake-shaped silver powders are defined as silver powders with aspect ratio of 2 or more, obtained by dividing the mean particle size (D50) of the flake-shaped silver powders by the mean thickness of the flake-shaped silver powders obtained by measurement with a scanning electron microscope. In one embodiment, the aspect ratio is 10 or more. In another embodiment, the aspect ratio is 20 or more. The mean particle size (D50) is a value obtained by measuring as described below. The mean thickness is represented by an average value of 50 measured values of thicknesses of the flake-shaped silver powders in a photograph taken with a scanning electron microscope.

In one embodiment, a scaly shape is preferable in terms of practical use from the viewpoints of being able to obtain more favorable and stable low electrical resistivity easily. In one embodiment, flake-shaped silver powders of the same shape are used preferably from the viewpoint of lower and stable electrical resistivity (and particularly, stable electrical resistivity).

In one embodiment, the mean particle size (D50) of the flake-shaped silver powders is 2.0-8.0 μm. In another embodiment, the mean particle size (D50) is 4.5-7.5 μm. In a still further embodiment, the mean particle size (D50) is 5.5-7.5 μm. The flake-shaped silver powder with the mean particle sizes (D50) within the above ranges can adequately decrease the electrical resistivity of the formed circuit lines. Flake-shaped silver powders with the mean particle size of 1.0 μm or more are superior in terms of production efficiency and handling.

The mean particle size (D50) of the flake-shaped silver powders refers to a value equal to 50% of the particle size distribution of the silver powders, and is obtained by measuring using a Particle Size Analyzer (Laser diffraction analysis machine X-100, Microtrac Inc.).

In one embodiment, the surface area (m²/g) of the flake-shaped silver powders is 0.7-1.7 (m²/g). In another embodiment, the surface area (m²/g) is 0.7-1.4 (m²/g). In a still further embodiment, the surface area (m²/g) is 0.7-1.2 (m²/g). The flake-shaped silver powder with such surface area can adequately decrease the electrical resistivity of the formed line.

In one embodiment, the tap density (g/cm³) of the flake-shaped silver powders is 1.0-5.0 (g/cm³), 1.5-4.5 (g/cm³) in another embodiment, 2.3-3.9 (g/cm³) in still further embodiment. The flake-shaped silver powder with such tap density (g/cm³) can adequately decrease the electrical resistivity of the formed line.

In one embodiment, to produce the flake-shaped silver powders, a method can used in which typical spherical or granular silver powders, obtained by liquid-phase reduction or atomization, are crushed with a ball mill or attritor, and then flattened by grinding by mechanical stress. According to this method, the flake-shaped silver powders can be obtained efficiently.

In one embodiment, besides the flake-shaped silver powders obtained by the above-mentioned method, crystalline flake-shaped silver powders obtained by crystallization can be used as flake-shaped silver powders. The flake-shaped silver powder obtained by crystallization has a further uniform particle size and a further uniform thickness and is favorable in dispersibility. By the use of such crystalline flake-shaped silver powders, superior formation of a coating film, high conductivity, and low melting point characteristics can be obtained. Accordingly, high-definition printing and a reduction in resistivity can be achieved. However, when flake-shaped silver powders are produced by crystallization, the required time and costs are increased, and there is a possibility that the production itself becomes inefficient. From this viewpoint, it is preferred that the flake-shaped silver powders produced by the above-mentioned general method are used.

### (b) Binder Resins—Polyvinyl Acetal Resins

In one embodiment, polyvinyl acetal resins can be used from the view point of the viscosity of paste composition.

In one embodiment, polyvinyl acetal resins are synthesized by an acetalization reaction of polyvinyl alcohol and aldehyde. In one embodiment, polyvinyl acetal resins are synthesized by a method in which acetalization is performed by saponification of vinyl ester polymer obtained by polymerization of a vinyl ester monomer such as vinyl acetate and causing vinyl alcohol polymer thus obtained to react with aldehydes.

In the present description, as polyvinyl acetal resins, polyvinyl acetal resins with 1 Pa·s or more of viscosity (measured with a Brookfield viscometer (25° C., 10 rpm)) in a di-propylene glycol methyl ether solution (10 wt %) are used.

When the viscosity is 1 Pa·s or more, an electrical circuit having a superior low resistivity can be efficiently formed even if a heat treatment is performed at a low temperature (for example, 120° C. or less).

In one embodiment, the acetalization degree of polyvinyl acetal resins is 60 (mol %) or more. In another embodiment, the acetalization degree is 65 (mol %) or more. In a still further embodiment, the acetalization degree is 70 (mol %) or more. When the acetalization degree is 60 (mol %) or more, an electrical circuit having a superior low resistivity can be efficiently formed even if a heat treatment is performed at a low temperature (for example, 120° C. or less).

In the present description, the acetalization degree can be determined as follows according to the method described in JIS K 6728 (1977).

The mass ratio (L0) of a vinyl alcohol unit which is not acetalized and the ratio (M0) of a vinyl acetate unit which is not acetalized are determined by titration. Subsequently, the mass ratio (K0) of an acetalized vinyl alcohol unit is determined from K0=1−L0−M0. Then, the ratio (L) of a vinyl alcohol unit which is not acetalized by mole and the ratio (M) of a vinyl acetate unit which is not acetalized by mole are calculated, and the ratio (K) of a vinyl alcohol unit which is acetalized by mole is calculated from a calculation formula, K=1−L−M.

Then, the acetalization degree (mol %) can be determined from K/{K+L+M}×100.

In one embodiment, the glass-transition point (Tg) of the polyvinyl acetal resins is 80° C. or more. In another embodiment, the glass-transition point (Tg) is 100° C. or more. In a still further embodiment, the glass-transition point (Tg) is 110° C. or more. When the glass-transition point is 80° C. or more, a problem of softening and damaging a coating film is less prone to occur even if the polyvinyl acetal resins are handled under a condition of relatively high temperature.

In one embodiment, specific examples of the polyvinyl acetal resins include polyvinyl acetal resins obtained by acetalization of vinyl alcohols with at least one kind selected from the group consisting of aldehydes such as formaldehyde, acetaldehyde, propionaldehyde, butylaldehyde, hexylaldehyde, benzaldehyde, and paraldehyde and the like. One kind of them can be used alone, or two or more kinds of them can be used in combination. The polyvinyl acetal resins are not limited thereto as long as they satisfy the above-described various physical properties.

Weight Ratio of (a) Flake-Shaped Silver Powders to (b) Polyvinyl Acetal Resin ((a)/(b))

In one embodiment, the weight ratio of (a) flake-shaped silver powders to (b) polyacetal resins ((a)/(b)) in the paste composition is in the range from 87/13 to 95/5. In another embodiment, the weight ratio ((a)/(b)) is in the range from 88/12 to 94/6. In a still further embodiment, the weight ratio ((a)/(b)) is in the range from 88/12 to 93/7. By the use of an electrically conductive composition with a weight ratio of (a)/(b) in the paste composition within the above ranges, an electrical circuit having superior low resistivity can be formed efficiently.

### (c) Solvent

The solvent is not particularly limited thereby provided it is a solvent that can dissolve the above binder resins. Examples of the solvent used in the present invention include ester solvents such as butyl acetate, ethyl acetate and carbitol acetate; ketone solvents such as methyl isobutyl ketone and cyclohexanone; aromatic solvents such as toluene and xylene; and glycol ether solvents including the acetate esters thereof such as the ethylene glycol butyl ether, propylene glycol methyl ether acetate and di-propylene glycol methyl ether. The organic solvent can be used either alone or in combinations thereof.

As mentioned below, in the case where the electrically conductive composition is applied on a predetermined substrate by printing and thereafter heated/cured or the like to form an electrical circuit, a solvent which does not chemically damage the substrate can be used. In the case where a defogger structure, an antenna structure, of vehicle window are formed using a polymer substrate such as a polycarbonate substrate, as a substrate, as the solvent, a solvent which does not chemically damage the substrate (polycarbonate sheet) can be used. In this case the solvent can be di-propylene glycol methyl ether in one embodiment.

### (d) Additives

As additives, in one embodiment, defoaming agents and dispersing agents can also be used as optional additives provided the properties of the conductive paste composition are not compromised thereby. Moreover, additional solvent can be added to adjust the viscosity of the paste composition. The amount of additives can be suitably determined by the persons skilled in the art. A plurality of additive types can also be used. The optional additives can be added at any time during preparation of the electrically conductive paste composition.

### (e) Solid Contents and Viscosity of the Conductive Paste Composition

In one embodiment, the weight ratio of solid contents (silver powders+binder resins) to solvent in the electrically conductive paste composition of the present invention is between 45:55 and 85:15. When the solid contents are within the above range, an electrically conductive composition which is favorable in applicability at the time of printing, exhibits fewer occurrences of reduction in viscosity and of separation between solid contents and a solution, and is superior in stability can be provided.

The viscosity of the electrically conductive paste composition of the present invention is adjusted to within the range of 1 to 30 Pa·s in one embodiment in the case the paste composition is dispersed. When the viscosity is within this range, an electrically conductive composition which can be uniformly applied on a substrate with ease can be provided.

The viscosity of the electrically conductive paste composition is a value obtained by measurement using a Brookfield viscometer (at 25° C., 10 rpm).

### (f) Preparation of the Electrically Conductive Paste Composition

The electrically conductive paste composition can be obtained by publicly known methods. For example, silver powders are thoroughly dispersed in binder resins (polyvinyl acetal resins) and solvent using a three-roll mill. When dispersion with a three roll mill is performed, in one embodiment, the silver powders and binder resins are dispersed in an amount of solvent smaller than the designated amount, and then the rest of the solvent is added to obtain the conductive paste composition with a proper viscosity.

### (g) Application Examples

By subjecting the electrically conductive composition of the present invention to a heat treatment (drying/curing) at a relatively low temperature (120° C. or less), an electrical circuit having a superior low resistivity can be efficiently formed on a substrate. The temperature of the heat treatment (drying/curing) is preferably 118° C. or less, more preferably 115° C. or less.

The substrate is not particularly limited, and a polymer substrate which is desired to be subjected to a heat treatment at a relatively low temperature is favorably used in formation of an electrical circuit. Specific examples of the polymer substrate include conventionally known polymer substrates such as a polycarbonate substrate, a polyethylene substrate, a polypropylene substrate and a polyethylene terephthalate.

One embodiment is applied to formation of an electrical circuit in an antenna or a defogger for vehicle window. Recently, in order to reduce the weight of vehicle itself, there is an example of using a plastic material as a substitute for an inorganic glass material as a material for use in vehicle window. Specifically, there are plural examples of vehicle windows using a polycarbonate sheet as a base material because of being superior in design. In the case of using a plastic material such as a polycarbonate material, there is a possibility of damaging the plastic material by a heat treatment at a high temperature. Therefore, when an electrical circuit is formed on a plastic substrate using a conventional electrically conductive paste required to be subjected to a heat treatment at a high temperature, the plastic base material is damaged by the heat treatment. By the use of the conductive composition of the present invention, an electrical circuit can be efficiently formed on a plastic substrate even if a heat treatment (drying/curing) is performed at a relatively low temperature (120° C. or less). Therefore, even in the case of using a plastic base material, an electrical circuit with, for example, superior low resistivity can be efficiently formed without damaging the base material. Moreover, the electrically conductive composition of the present invention can be applied to formation of a circuit of MTS, formation of a transceiving antenna of RF-ID, and the like.

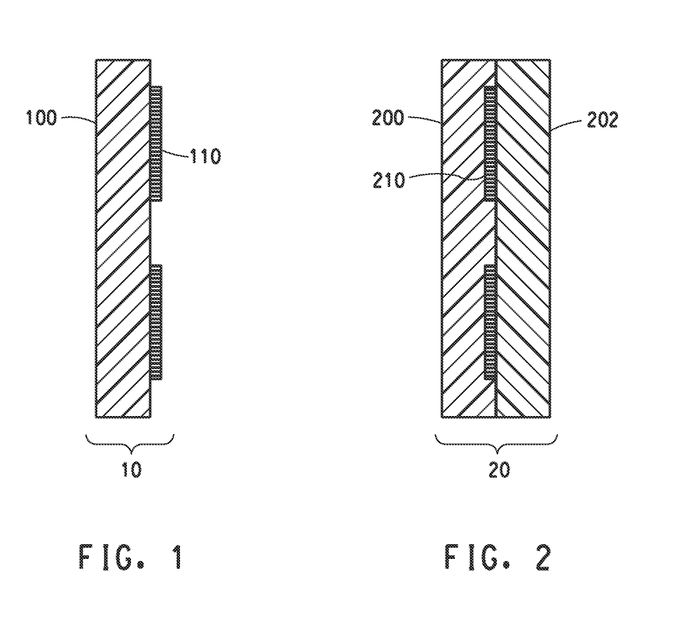

Forming an Electrical Circuit-Antenna Structure of Vehicle Windows Next, a method of producing an antenna structure of vehicle, including an electrical circuit, using the electrically conductive paste of the present invention, is described with reference to FIGS. 1 to 3.

In one embodiment, the antenna structure of vehicle is produced by applying the electrically conductive paste of the present invention on a polymer substrate so as to have a predetermined pattern and subjecting the electrically conductive paste-applied polymer substrate to a heat treatment (heating/curing) at 120° C. which is a relatively low temperature.

In one embodiment, the time of the heat treatment (heating/curing) may be a short time of about 30 minutes. In one embodiment, as the method for the applying, any of conventionally known various printing methods such as screen printing and stencil printing, for use in formation of a circuit pattern by applying an electrically conductive paste on a substrate or a method of applying with a nozzle can be applied.

In one embodiment, an antenna structure 10 may have a configuration of forming an electrical circuit 110 on one surface side of a polymer substrate (polymer substrate 100) (FIG. 1). In another embodiment, an antenna structure 20 has a laminate configuration of having an electrical circuit 210 between two polymer substrates 200 and 202 (FIG. 2).

In the case where an antenna structure 20 having a laminate configuration is formed as in the latter case, for example, the antenna structure having a laminate configuration can be efficiently obtained by Sheet Inserted Injection Molding. Specifically, in one embodiment, in the state where a sheet-like polymer substrate (polymer substrate 200) on which an electrical circuit 210 has been formed is set in a predetermined mold such as a metal mold, the laminate is heated and molded at a predetermined temperature while injecting a resin. Thus, the antenna structure 20 having a laminate configuration can be efficiently produced. According to this molding, a laminate having a gradually curved surface required in designing a vehicle window can be efficiently formed.

As shown in FIG. 3, a pattern of an electrical circuit 310 in an antenna structure 30 of vehicle is formed in a circuit on a polymer substrate 300 which is a vehicle window. In one embodiment, a signal received from the electrical circuit 310 in the antenna structure 30 is received by a receiver 330 via a connector 320 provided as appropriate. In one embodiment, a material of the polymer substrate 300 which is a vehicle window can be polycarbonate. In one embodiment, the connector 320 which can be provided as appropriate in the antenna structure 30 is provided by a conventionally known method after production of the antenna structure 30. Examples of the receiver 330 include conventionally known receivers such as a radio receiver and a television receiver. The electrically conductive paste of the present invention can be favorably applied to all of conventionally known antenna structures of vehicle in addition to the antenna structure of vehicle specifically described in this description. For example, the electrically conductive paste of the present invention can be publicly applied to antenna structures disclosed in JP 2006-35592 A and JP 2008-306399 A, for example.

Physical Properties of Electrical Circuit

In one embodiment, in the case where an electrical circuit is formed under the following conditions using the electrically conductive composition of the present invention, e.g., implementation of heat processing (drying and curing) for 30 minutes at 120° C. on a glass substrate, the resistivity of the obtained electrical circuit is 7-20 (μΩ·cm), for example. In another embodiment, the resistivity is 8-19 (μΩ·cm). In a still further embodiment, the resistivity is 9-18 (μΩ·cm).

By the use of the electrically conductive composition of the present invention, an electrical circuit having superior low resistivity can be efficiently formed even if a heat treatment is performed at a relatively low temperature. Thus, an electrical circuit can be favorably formed on a plastic substrate and the like other than an inorganic glass.

### EXAMPLES

The present invention is explained in detail below with examples, but these examples are merely illustrations and are not intended to limit the present invention thereto.

### 1. Manufacturing Example

### Preparation of Paste

(a) Silver powders, (b) Binder resins and (c) Solvent were mixed in the amounts shown in Table 1. The resulting mixtures were kneaded in a three-roll mill to obtain the Pastes 1 to 6 and Comparative Pastes 1 to 5.

### Materials:

(a) Silver powders: Flake-shaped silver powder (Mean particle size (D50)=6.40 μm, Surface Area=1.00 m²/g, Tap Density=2.90 g/cm³)
(b) Binder resins:
(b-1): Polyvinyl acetal resin (acetalization degree: 74 (mol %), glass-transition point (Tg)=110° C.)
(b-2): Polyvinyl butyroacetal resin(acetalization degree: 0 (mol %), glass-transition point (Tg)=60° C.)
(b-3): Polyvinyl acetal resin (acetalization degree: 74 (mol %), glass-transition point (Tg)=107° C.)

### (c) Solvent:

(c-1): Di-propylene glycol methyl ether
(c-2): Carbitol acetate

### 2. Measurement of Electrical Resistivity

The electrical resistivity (lateral electrical resistivity) of a circuit line formed using the above paste composition was measured in the manner described below. All measurements were carried out twice. All values shown in the table 1 indicate the average values thereof.

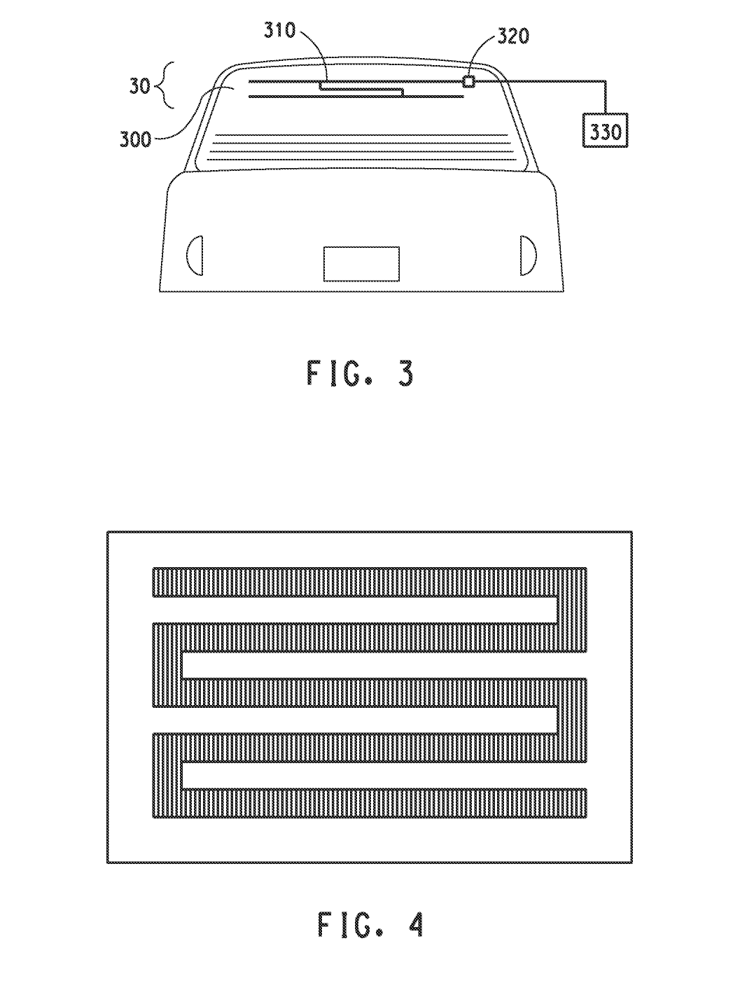

The paste compositions were coated onto glass substrates according to the procedure described below.
1) A glass substrates measuring 75 mm×50 mm×2 mm were prepared. Each of the paste compositions shown in Table 1 was then respectively coated onto each of the prepared glass substrates so as to depict the shape shown in FIG. 4. More specifically, coating was carried out in the manner described below. First, a plastic film having a cutout in the shape of a circuit pattern was affixed to the surface of each glass substrate. Next, the above-mentioned paste compositions were coated onto the substrates after having affixed each plastic film. The shape of the coated pattern was 4 mm wide and 274 mm long (total length).
2) Each of the substrates on which the circuit pattern had been coated and formed was heated and dried by placing in a box oven for 0.5 hour at 120° C. to cure the circuit pattern. As a result, an electrically conductive circuit line was formed on each glass substrate to obtain each of the samples of Examples 1 to 6 and Comparative Examples 1 to 5 for measuring lateral electrical resistivity (μΩ·cm).

Lateral electrical resistivity of the circuit line was measured by placing a probe on both ends of the line that had been cured and formed on the glass substrates for each of the samples obtained in the manner described above. The results are shown in Table 1.

TABLE 1

| | Ex. 1 | Ex. 2 | Ex. 3 | Ex. 4 | Ex. 5 | Ex. 6 | Co. Ex1 | Co. Ex2 | Co. Ex3 | Co. Ex4 | Co. Ex5 |
|---|---|---|---|---|---|---|---|---|---|---|---|
| Paste | Paste1 | Paste2 | Paste3 | Paste4 | Paste5 | Paste6 | Co.Paste1 | Co.Paste2 | Co.Paste3 | Co.Paste4 | Co.Paste5 |
| Composition | | | | | | | | | | | |
| (a)Silver | 42.31 | 47.37 | 53.49 | 61.04 | 53.49 | 61.04 | 38.05 | 70.59 | 70.59 | 63.3 | 69.7 |
| powder | | | | | | | | | | | |
| (wt %) | | | | | | | | | | | |
| (b)Binder | (b-1) | (b-1) | (b-1) | (b-1) | (b-1) | (b-1) | (b-1) | (b-1) | (b-1) | (b-2) | (b-3) |
| Resin | 5.77 | 5.26 | 4.65 | 3.90 | 4.65 | 3.90 | 6.19 | 2.94 | 2.94 | 5.50 | 6.06 |
| (wt %) | | | | | | | | | | | |
| (b)*Viscosity | 61 | 61 | 61 | 61 | 61 | 61 | 61 | 61 | 61 | 0.77 | 0.23 |
| (Pa · s) | | | | | | | | | | | |
| (c)Solvent | (c-1) | (c-1) | (c-1) | (c-1) | (c-2) | (c-2) | (c-1) | (c-1) | (c-2) | (c-1) | (c-1) |
| (wt %) | 51.92 | 47.37 | 41.86 | 35.06 | 41.86 | 35.06 | 55.75 | 26.47 | 26.47 | 31.19 | 24.24 |
| Total (wt %) | 100 | 100 | 100 | 100 | 100 | 100 | 100 | 100 | 100 | 100 | 100 |
| Weight | 88/12 | 90/10 | 92/8 | 94/6 | 92/8 | 94/6 | 86/14 | 96/4 | 96/4 | 92/8 | 92/8 |
| ratio of | | | | | | | | | | | |
| (a) to (b) | | | | | | | | | | | |
| Resistivity | 19.5 | 13.9 | 11.7 | 15.2 | 10.3 | 11.8 | 29.8 | 23.8 | 27.6 | 25.1 | 74.2 |
| (μΩ · cm) | | | | | | | | | | | |

(b)*Viscosity (Pa · s) in Table 1 represents viscosity (measured with a Brookfield LVT viscometer (25° C., 10 rpm)) of a 10 wt % solution obtained by dissolving binder resin used in each of the examples and the comparative examples in di-propylene glycol methyl ether solvent.

What is claimed is:

1. An electrically conductive paste composition for forming an electrical circuit comprising:
(a) a flake-shaped silver powder, wherein the mean particle size (D50) of the silver powder is 2.0 to 8.0 μm;
(b) a polyvinyl acetal resin, wherein the viscosity of a 10 wt % solution of the polyvinyl acetal resin in di-propylene glycol methyl ether is no less than 1 Pa·s as measured with a Brookfield viscometer (10 rpm, at 25° C.); and wherein the weight ratio of (a) to (b) is in the range from 87/13 to 95/5.

2. The electrically conductive paste composition of claim 1, wherein the weight ratio of (a) to (b) is in the range from 88/12 to 94/6.

3. The electrically conductive paste composition of claim 1, wherein the weight ratio of (a) to (b) is in the range from 88/12 to 93/7.

4. The electrically conductive paste composition of claim 1, wherein the acetalization degree of (b) is no less than 60 mol %.

5. The electrically conductive paste composition of claim 1, wherein the surface area of (a) is 0.7-1.7 m²/g.

6. A method of forming an electrical circuit on a polymer substrate, comprising the steps of:
(1) applying an electrically conductive paste comprising:
(a) a flake-shaped silver powder, wherein the mean particle size (D50) of the silver powders is 2.0 to 8.0 μm; and
(b) a polyvinyl acetal resin, wherein the viscosity of a 10 wt % solution of the polyvinyl acetal resin in di-propylene glycol methyl ether is no less than 1 Pa·s as measured with a Brookfield viscometer (10 rpm, at 25° C.); and wherein the weight ratio of (a) to (b) is in the range from 87/13 to 95/5, onto the polymer substrate, thereby forming an electrical conductor pattern; and
(2) heat-curing the formed electrical conductor pattern at 120° C. or lower.

7. The method of forming an electrical circuit on a polymer substrate of claim 6, wherein the polymer substrate is a polycarbonate substrate.
